(19) United States
(12) Patent Application Publication
(10) Pub. No.: US 2011/0234565 A1
(43) Pub. Date: Sep. 29, 2011

(54) SHIFT REGISTER CIRCUIT, DISPLAY DEVICE, AND METHOD FOR DRIVING SHIFT REGISTER CIRCUIT

(75) Inventors: Hideki Morii, Osaka (JP); Akihisa Iwamoto, Osaka (JP); Takayuki Mizunaga, Osaka (JP); Yuuki Ohta, Osaka (JP); Kei Ikuta, Tottori (JP)

(73) Assignee: Sharp Kabushiki Kaisha, Osaka-shi, Osaka (JP)

(21) Appl. No.: 12/998,766

(22) PCT Filed: Aug. 7, 2009
(86) PCT No.: PCT/JP2009/063998

§ 371 Date: May 31, 2011

(30) Foreign Application Priority Data
Dec. 12, 2008 (JP) 2008-316655

(51) Int. Cl. G06F 3/038; G11C 19/00

(52) U.S. Cl. 345/211; 377/78; 377/79

(57) ABSTRACT

In at least one embodiment, under a non-load condition of a first supply line for a first clock signal and a second supply line for a second clock signal, a fall time of a clock pulse of the first clock signal, which is supplied to the first supply line, is longer than that of the second clock signal, which is supplied to the second supply line.

### TECHNICAL FIELD

The present invention relates to a shift register circuit which is monolithically provided in to a display panel.

### BACKGROUND ART

In these years, the fabrication of a monolithic gate driver has been developed for the purpose of cost reduction. The monolithic gate driver is such a gate driver that is formed from amorphous silicon on a liquid crystal panel. The term “monolithic gate driver” is also associated with the terms such as “gate driver-free”, “built-in gate driver in panel”, and “gate in panel”.

FIG. 9 illustrates a configuration example of a shift register circuit constituting a monolithic gate driver.

According to the shift register circuit, each of shift registers SR ( . . . , SRn-1, SRn, SRn+1, . . . ) has a set input terminal Gn-1, an output terminal Gn, a reset input terminal Gn+1, a Low-voltage supply input terminal VSS, and a clock signal input terminal CK. An output signal OUT ( . . . , OUTn-1, OUTn, OUTn+1, . . . ) is supplied to the set input terminal Gn-1 from a followed shift register. The output signal OUT is supplied to a corresponding scan signal line via the output terminal Gn. An output signal OUT of each shift register is supplied to the reset input terminal Gn+1 of each followed shift register. A Low supply voltage VSS, which is a low-level power supply voltage, is supplied to each of the shift registers SR, via a corresponding Low-voltage supply input terminal VSS. A clock signal CK1 is supplied to a clock signal input terminal CK of one of any adjacent two shift registers SR, and a clock signal CK2 is supplied to a clock signal input terminal CK of the other of the adjacent two shift registers SR. The clock signal CK1 and the clock signal CK2 have a phase relation in which active clock pulse periods of the clock signal CK1 and those of the clock signal CK2 do not overlap each other (see FIG. 11). Each of the clock signals CK1 and CK2 has a High-level voltage VGH or a Low-level voltage VGL. The Low-level voltage VGL of the clock signals CK1 and CK2 is equal to the Low supply voltage VSS.

FIG. 10 illustrates a configuration example of a shift register SR included in the shift register circuit shown in FIG. 9. This configuration is disclosed in Non Patent Literature 1.

Each of the shift registers SR has (i) four transistors Tr1, Tr2, Tr3, and Tr4 and (ii) a capacitor CAP1. The four transistors Tr1, Tr2, Tr3, and Tr4 are all n-channel TFTs.

The transistor Tr1 has (i) a gate and a drain which are connected with the set input terminal Gn-1 and (ii) a source which is connected with a gate of the transistor Tr4. The transistor Tr4 has (i) a drain which is connected with the clock signal input terminal CK and (ii) a source which is connected with the output terminal Gn. That is, the transistor Tr4 serves as a transfer gate to pass through or block off a clock signal which has been supplied to the clock signal input terminal CK. The capacitor CAP1 is provided between the gate and the source of the transistor Tr4. A node having an electric potential which is identical to that of the gate of the transistor Tr4 is referred to as a node netA.

The transistor Tr2 has (i) a gate which is connected with the reset input terminal Gn+1, (ii) a drain which is connected with the node netA, and (iii) a source connected with the Low-voltage supply input terminal VSS. The transistor Tr3 has (i) a gate which is connected with the reset input terminal Gn+1, (ii) a drain which is connected with the output terminal Gn, and (iii) a source which is connected with the Low-voltage supply input terminal VSS.

The following describes operation of each of the shift registers SR having a circuit configuration shown in FIG. 10, with reference to FIG. 11.

The transistors Tr3 and Tr4 remain in a high-impedance state until a shift pulse is supplied to the set input terminal Gn-1. The output terminal Gn remains at Low until the shift pulse is supplied to the set input terminal Gn-1.

While a gate pulse, which is the shift pulse, of an output signal OUT (OUTn-1 in FIG. 11) is being supplied to the set input terminal Gn-1 from a followed shift register, (i) an output pulse is generated and outputted via the output terminal Gn and (ii) the transistor Tr1 is in an ON state so as to charge the capacitor CAP1. As the capacitor CAP1 is charged, an electric potential of the node netA increases so that the transistor Tr4 turns on. This causes a clock signal, which has been supplied to the clock signal input terminal CK to be applied to the source of the transistor Tr4. At a moment when a clock pulse is supplied to the clock signal input terminal CK, the electric potential of the node netA precipitously raises due to a bootstrap effect of the capacitor CAP1, and therefore the clock pulse thus supplied is outputted as a gate pulse (in this case, as a pulse of the output signal OUTn) via the output terminal Gn of the shift register SR.

When the supply of the gate pulse to the set input terminal Gn-1 ends, the transistor Tr1 turns off. Then, the transistors Tr2 and Tr3 are caused to turn on in response to a reset pulse supplied to the reset input terminal Gn+1 so that the Low supply voltage VSS is applied to the node netA and the output terminal Gn. This allows the electric charge, which has been caused by the floating of the node netA and the output terminal Gn of the shift register SR, to be discharged. Accordingly, the transistor Tr4 turns off. When the supply of the reset pulse ends, the output pulse generating period of the output terminal Gn ends, and another Low-maintaining period of the output terminal Gn newly starts.

Gate pulses are thus successively supplied to gate lines.

According to the shift register circuit, the transistors Tr3 and Tr4 are being in a high-impedance state during the Low-maintaining period of the output terminal Gn. This causes the output terminal Gn to become floating. In view of this, a so-called sink-down transistor (for causing an output terminal of a shift register to become a low level) is provided so that the Low supply voltage VSS which is at a Low level is applied to the output terminal Gn in the Low-maintaining period, in order to prevent a case where the output terminal Gn cannot maintain the Low due to a factor such as noise propagated by a cross coupling between a gate bus line and a source bus line. Moreover, during the Low-maintaining period, the transistor Tr2 is being at a high-impedance state and therefore the node netA becomes floating. In view of this, another transistor for causing an output terminal of a shift register to become a low level is provided so that the supply voltage VSS which is at the Low level is applied to the node netA in the Low-maintaining period, in order to prevent the transistor Tr4 from causing a leakage.

However, as disclosed in Non Patent Literature 1, in the case where the transistor, via which the Low level is applied to the output terminal Gn and the node netA, is provided, DC bias is constantly applied to a gate of the transistor for causing an output terminal of a shift register to become a low level. This causes a phenomenon in which a threshold voltage is shifted. The phenomenon of the threshold voltage shift is particularly noticeable under a high temperature condition. In a case where a TFT is an n-channel TFT, a threshold voltage is shifted to rise. In a case where a phenomenon of threshold voltage shift is caused in a transistor, via which a Low level is applied to the output terminal Gn, the transistor gradually becomes difficult to turn on. This makes it difficult for the transistor to allow the Low level to be applied to the output terminal Gn. Moreover, in a case where a phenomenon of threshold voltage shift is caused in a transistor, via which a Low level is applied to the node netA, the transistor gradually becomes difficult to turn on. This makes it difficult for the transistor to allow the Low level to be applied to the node netA. Accordingly, in a case where an electric potential of the node netA is raised due to factors such as an unstable electric potential and leakages of transistors, an output transistor (transistor Tr4 in FIG. 10) causes a leakage, and this also makes it difficult for the output terminal Gn to maintain the Low level.

Such a phenomenon of threshold voltage shift prevent the TFT, which has the gate to which DC bias is constantly applied, from achieving its switching function under a prolonged operation. Ultimately, the shift register circuit comes to fail to fulfill its primary function and instead malfunctions. This prevents suppression of an effect of an electric potential change, which effect is exerted from a source bus line, etc. on a gate bus line, and accordingly a stable display cannot be carried out due to a cause such as a crosstalk.

In view of this, Non Patent Literature 1 proposes a shift register circuit in which a period, during which an ON-voltage is being applied to a gate of such a sink-down TFT, is shortened.

FIGS. 12 and 13 illustrate a configuration of a shift register circuit which is similar to the above described shift register circuit.

The shift register circuit shown in FIG. 12 includes shift registers SR each of which has clock signal input terminals CKa and CKb instead of the clock signal input terminal CK, which is provided in each of the shift registers SR of the shift register circuit shown in FIG. 9. In each of the shift registers SR, one of the clock signals CK1 and CK2 is supplied to one of the clock signal input terminals CKa and CKb, whereas the other of the clock signals CK1 and CK2 is supplied to the other of the clock signal input terminals CKa and CKb. Specifically, in one of any adjacent two shift registers, (i) a clock signal CK1 is supplied via a clock signal input terminal CKa and (ii) a clock signal CK2 is supplied via a clock signal input terminal CKb. In the other of the any adjacent two shift registers, (i) a clock signal CK2 is supplied via a clock signal input terminal CKa and (ii) a clock signal CK1 is supplied via a clock signal input terminal CKb. The clock signal CK1 and the clock signal CK2 have a phase relation in which active clock pulse periods of the clock signal CK1 and the clock signal CK2 do not overlap each other (see FIG. 14). Each of the clock signals CK1 and CK2 has a High-level voltage VGH or a Low-level voltage VGL. The Low-level voltage VGL of the clock signals CK1 and CK2 is equal to the Low supply voltage VSS.

FIG. 13 illustrates a configuration example of each of the shift registers SR included in the shift register circuit shown in FIG. 12.

The configuration of each of the shift registers SR shown in FIG. 13 further includes, in addition to the configuration shown in FIG. 10, (i) transistors Tr5 through Tr7 each of which is a sink- down n-channel TFT and (ii) an AND gate 101 which has two input terminals.

The transistor Tr5 has (i) a gate which is connected with the clock signal input terminal CKa, (ii) a drain which is connected with the node netA, and (iii) a source which is connected with the output terminal Gn. The transistor Tr6 has (i) a gate which is connected with an output of the AND gate 101, (ii) a drain which is connected with the output terminal Gn, and (iii) a source which is connected with the Low-voltage supply input terminal VSS. The transistor Tr7 has (i) a gate which is connected with the clock signal input terminal CKb, (ii) a drain which is connected with the output terminal Gn, and (iii) a source which is connected to the Low-voltage supply input terminal VSS. The AND gate 101 has the two input terminals one of which is connected with the clock signal input terminal CKa and the other, which is a low-active input terminal, is connected with the output terminal Gn.

The following describes operation of each of the shift registers SR configured as shown in FIG. 13, with reference to FIG. 14.

An output signal OUT is supplied to the output terminal Gn in a similar way to that of the configuration shown in FIG. 11. However, during a Low-maintaining period of the output terminal Gn, the transistors Tr5, Tr6, and Tr7 and the AND gate 101 function additionally.

The transistor Tr5 turns on in response to a clock pulse of the clock signal CK1 or CK2 (clock signal CK1 in FIG. 14) which is supplied to the clock signal input terminal CKa. This causes the node netA to be electrically connected to the output terminal Gn. The AND gate 101 outputs a High level in response to a clock pulse of a clock signal (the clock signal CK1 in FIG. 14) which is supplied to the clock signal input terminal CKa as long as the output terminal Gn is in a Low level. This causes the transistor Tr6 to turn on. The transistor Tr7 turns on in response to a clock pulse of the clock signal CK1 or CK2 (clock signal CK2 in FIG. 14) which is supplied to the clock signal input terminal CKb. This causes the output terminal Gn to be electrically connected to the Low supply voltage VSS.

The output terminal Gn is caused to become a low level during a first period in which the transistor Tr6 is in the ON state and during a second period in which the transistor Tr7 is in the ON state, the first and second periods being alternated. Moreover, since the transistor Tr6 is in the ON state while the transistor Tr5 is in the ON state, the node netA is caused to become a low level while the transistors Tr5 and Tr6 are in the ON state.

According to the operation shown in FIG. 14, the period during which the output terminal Gn is caused to become a low level is such a long period that is a sum of clock pulse periods of the clock signals CK1 and CK2. Despite this, DC bias, at the same ratio as the ON-duty ratio of approximately 50% regarding the clock signals, is to be applied to each of the gates of the respective transistors Tr6 and Tr7. The same applies to a DC bias period of the transistor Tr5.

In this manner, the shift register circuit configured as shown in FIGS. 12 through 14 reduces a time period during which DC bias is being applied to the sink-down TFTs, and thereby a phenomenon of threshold voltage shift is suppressed.

The conventional shift register circuit shown in FIGS. 12 through 14, in which the time period during which the DC bias is being applied to the sink-down TFTs is reduced to approximately 50%, is considered to be durable against aging with prolonged operation under a high temperature condition of 50° C., which is generally considered as a maximum operable temperature of a shift register used in a device such as a laptop computer. However, an application of TFT liquid crystal modules is not limited to an OA (office automation) application such as to laptop computer and a monitor, but the TFT liquid crystal modules have been used in wider fields such as FA (factory automation), IA (industry application), and in-vehicle application. In accordance with this, it is demanded to accomplish a technique for realizing an operation under a higher temperature conditions such as of 85° C. (for IA application) and of 95° C. (for in-vehicle application), which conditions are severer than the temperature of 50° C., which is a higher limit of the operable temperature range demanded for the TFT liquid crystal module.

That is, it is demanded to realize a gate-monolithic shift register circuit made of amorphous silicon and has reliability higher than that of the configuration shown in FIGS. 12 through 14.

FIG. 15 is a graph illustrating relations, which were researched by the applicant of the present invention, between (i) shift amounts ΔVth of threshold voltages and (ii) time periods during which DC bias is being applied to a gate, with regard to two types (type 1 and type 2) of TFTs. The type 1 and the type 2 have (i) identical channel lengths L of 4 μm, (ii) identical channel widths W of 100 μm, and (iii) respective different structural shapes. A source voltage Vs is 0 V, a drain voltage Vd is 0.1 V, and a temperature is 85° C. The type 1 and the type 2 show similar shift amounts ΔVth. In a case where a gate voltage Vg is DC 20 V, the shift amounts ΔVth are drastically increased, as compared to a case where the gate voltage Vg is DC 10 V. As described above, the shift amounts ΔVth of threshold voltages of the TFTs are largely attributable to the DC bias applied to the gates.

### Citation List

### Patent Literature 1

Japanese Patent Application Publication, Tokukai, No. 2005-50502 (Publication Date: Feb. 24, 2005) Non Patent Literature 1

Seung-Hwan Moon et al., “Integrated a-Si:H TFT Gate Driver Circuits on Large Area TFT-LCDs”, SID 2007 46.1, pp 1478-1481

### SUMMARY OF INVENTION

### Technical Problem

According to an amorphous silicon TFT, it is well known that a characteristic of a threshold voltage is shifted in accordance with a time period during which an ON-voltage is being applied to a gate, as described above. Moreover, it has come to be revealed that a gate-monolithic shift register circuit made of the amorphous silicon malfunctions under a high temperature mainly due to a current leakage caused while an output transistor is in an OFF state. This relates to a temperature characteristic of the amorphous silicon TFT that a current while the amorphous silicon TFT is in an OFF state increases as the temperature increases. The gate-monolithic shift register circuit made of amorphous silicon is made up of a plurality of shift registers, which are made of amorphous silicon and provided for each of (several hundreds to several thousands of) scanning lines. Note however that, only one of the shift registers is in an ON state (outputting a High level), and the others are being in an OFF state (outputting a Low level). Therefore, respective control circuits, which control output transistors (e.g., the transistor Tr4 shown in FIG. 13), of most of the shift registers carry out OFF controls so as to cause corresponding ones of the output transistors to be in OFF states.

When a current of the amorphous silicon TFT being in an OFF state is slightly increased due to a temperature, thus slightly increased current is multiplied by the number (several hundreds to several thousands) of the shift registers and thereby increased so much as to round waveforms of respective clock signals. Consequently, the control circuit is adversely affected and thereby cannot control the output transistor appropriately. This is a main factor which causes the malfunction of the gate-monolithic shift register circuit. In view of this, it is preferable that a clock signal for controlling a gate-monolithic shift register circuit, which is made of amorphous silicon, (i) is supplied from a supply source having an output impedance (output resistance of a transistor being in an ON state) which is as low as possible and (ii) has a waveform with a precipitous rising edge and a precipitous falling edge, in order to stably drive the shift register circuit even when the current leakage of the output transistor is increased under the high temperature condition.

The following describes details of relations among (i) waveform rounding of a clock signal, (ii) a leakage of an output transistor being in an OFF state, which output transistor is included in each of the shift registers, and (iii) malfunctions of the shift register circuit.

According to the conventional shift register circuit shown in FIGS. 12 through 14, each of the shift registers SR transfers a clock signal CK1 or CK2, which has been supplied to the clock signal input terminal CKa, to an output terminal OUT via the transistor Tr4. This causes a problem as follows. That is, while the transistor Tr4 is in an ON state, a clock signal line, through which the clock signal CK1 or CK2 is supplied to the shift register circuit, is being connected with a scan signal line. This causes an interconnect delay (referred to as a first delay) of a clock signal in the clock signal line to become long. Moreover, even while the transistor Tr4 is in an OFF state, an interconnect delay (referred to as a second delay) of a clock signal in the clock signal line also becomes long, due to a leakage existing between the drain and the source of the transistor Tr4 in a subthreshold region. In particular, in a case where the transistor Tr4 is made of amorphous silicon having small mobility, a drastically large channel width of millimeter order is secured by a configuration such as that in which a drain electrode is engaged with a source electrode in a gearing manner, in order to obtain channel conductance enough to output a gate pulse. This tends to induce conduction due to leakage defects in somewhere in a channel area, regardless of subthreshold conduction in the subthreshold region. Note that the first delay is longer than the second delay.

Therefore, a drastically long interconnect delay is imposed on one of the clock signals CK1 and CK2, which one is supplied to a clock signal input terminal CKa of a certain shift register SR, which is in a period of supplying a clock signal to the output terminal OUT. Such a drastically long interconnect delay is caused due to a sum effect (referred to as a first sum effect) of a first delay of the certain shift register SR and a second delay of every other (alternate) shift register SR with respect to the certain shift register SR. On the other hand, the other one of the clock signals CK1 and CK2, which other one is supplied to a clock signal input terminal CKa of another shift register SR, is subjected to a relatively long interconnect delay caused due to a sum effect (referred to as a second sum effect) of second delays of the another shift register SR and every other (alternate) shift register SR with respect to the another shift register SR. The first sum effect causes a delay which is longer than that caused by the second sum effect.

In a case where waveform rounding caused by interconnect delays of the clock signals CK1 and CK2 are large, a rising edge and a falling edge of the waveforms become gentle. This causes a transistor, which has a gate to which the clock signal CK1 or CK2 is supplied, to have a gate voltage with a waveform in which (i) a time period from a time point when a rising edge of the waveform starts to a time point when the gate voltage becomes higher than a threshold voltage is longer and (ii) a time period from a time point when a falling edge of the waveform starts to a time point when the gate voltage becomes lower than the threshold voltage is longer, as compared to a case where interconnect delays are shorter. This causes the transistor to turn on and off at respective timings which are lagged behind corresponding proper timings.

This may cause a hazard in which, for example, a transistor Tr7 of a certain shift register turns on in response to a clock signal, which (i) has been supplied to a clock signal input terminal CKb and (ii) is subjected to a shorter delay (which is caused due to a second sum effect), before a clock signal, which (i) has been supplied to a clock signal input terminal CKa and (ii) is subjected to a longer delay (which is caused due to a first sum effect), is transmitted to an output terminal Gn. Moreover, clock signals CK1 and CK2 are alternately subjected to longer delays in accordance with a shift register SR, which is to carry out an output, being switched between an odd-numbered stage and an even-numbered stage. Therefore, such a hazard can cause the shift register circuit to malfunction.

According to the conventional shift register circuit, a clock signal is (i) used as an output signal supplied to the scan signal line and (ii) used for causing an output terminal of each of the shift registers to become a low level, as described above. Such a conventional shift register circuit has a problem that the shift register circuit malfunctions due to interconnect delays of the clock signals.

The present invention is accomplished in view of the conventional problem, and its object is to realize a shift register circuit which can prevent malfunction from occurring due to an interconnect delay of a clock signal, even though each shift register has a configuration in which (i) one clock signal is supplied as an output signal of the each shift register and (ii) the other clock signal is supplied as a driving signal of the each shift register. Further, another object of the present invention is to realize (i) a display device including the shift register circuit and (ii) a method for driving the shift registers.

### Solution to Problem

In order to attain the object, in a shift register circuit of the present invention, (i) a first clock signal which is made up of at least one clock signal and (ii) a second clock signal which is made up of at least one clock signal, are supplied to said shift register circuit, and the shift register circuit includes: a plurality of shift registers which are connected to each other in series, each of the plurality of shift registers receiving (i) a predetermined one of the first clock signal, which is to be transmitted to an output terminal of the each of the plurality of shift registers via a corresponding switching element and then outputted as a corresponding output signal and (ii) a predetermined one of the second clock signal, which serves as a signal for driving a first circuit included in the each of the plurality of shift registers, and in a case where said shift register circuit serves as a load on first and second supply lines, via which the first clock signal and the second clock signal are respectively supplied, under a non-load condition of the supply lines, fall time of a clock pulse of the first clock signal, which is supplied via the first supply line, being longer than that of the second clock signal, which is supplied via the second supply line.

According to the configuration, each of the plurality of shift registers receives (i) a predetermined one of the first clock signal, which is to be transmitted to an output terminal of the each of the plurality of shift registers via a corresponding switching element and then outputted as a corresponding output signal, and (ii) a predetermined one of the second clock signal, which serves as a signal for driving a first circuit included in the each of the plurality of shift registers. This prevents a waveform of the second clock signal from being affected, even in a case where a line, which is connected to the output terminal of each of the plurality of shift registers, serves as a load on the first clock signal (i) during an ON state of the switching element or (ii) when a leakage occurs in a subthreshold region during an OFF state of the switching element. Therefore, it is possible to set a timing of driving the first circuit with the second clock signal, independently from that with the first clock signal.

In a case where the shift register circuit serves as a load on first and second supply lines, via which the first clock signal and the second clock signal are respectively supplied and the first and second supply lines are in a non-load condition, a fall time of a clock pulse of the first clock signal, which is supplied via the first supply line, is longer than that of the second clock signal, which is supplied via the second supply line. This makes it possible to prevent fall time from being increased due to a further interconnect delay, even in a case where a line becomes a load on the first clock signal. The line is connected to the output terminal of each of the plurality of shift registers via the switching element which turns ON or OFF.

This makes it easy to set, in advance, the first clock signal and the second clock signal so that the shift register circuit hardly has malfunction, by causing the first clock signal and the second clock to have such a phase relation that active periods of the first clock signal do not overlap those of the second clock signal under the non-load condition.

This makes it possible to realize a shift register circuit which can prevent malfunction from occurring due to an interconnect delay of a clock signal, even though each shift register has a configuration in which (i) one of the clock signal is supplied as an output signal of the each shift register and (ii) the other clock signal is supplied as a driving signal of the each shift register.

In a case where each fall time of the clock pulse is set to be sufficiently long before the clock pulse is supplied to the shift register circuit, it is easy to prevent the fall time from being further increased due to an interconnect delay when the first clock signal is supplied to the line which is connected to the output terminal of the shift register circuit. This allows each fall time of the pulses supplied to the line to be substantially uniform in a panel plane. Therefore, feed-through voltages ΔV become uniform in a liquid crystal display panel plane, even in a case where a so-called feed-through phenomenon occurs via a parasitic capacitor defined by a picture element electrode and a gate line after a data signal is written into a picture element in the liquid crystal display panel. This greatly contributes to a display with high quality.

In order to attain the object, according to the shift register circuit of the present invention: the first clock signal and the second clock signal have (i) identical High-level voltages and (ii) identical Low-level voltages. It follows that the first clock signal and the second clock signal can share a single voltage supply. This makes it possible to reduce a size of a voltage supply circuit which supplies voltages to the shift register circuit. Moreover, an amplitude of each clock pulse of the second clock signal becomes equal to a large amplitude of each clock pulse of the first clock signal, which is used as an output signal of the shift register circuit, and therefore the pulse comes to have higher electric power. This makes it possible to enhance a driving capability of the first circuit.

In order to attain the object, according to the shift register circuit of the present invention: the first clock signal has a waveform which is obtained by delaying, in accordance with a time constant, a waveform of any one of the clock signals which constitute the second clock signal.

According to the configuration, it is possible to easily generate, with the use of a circuit such as a CR delay circuit, a first clock signal from a second clock signal which has a rectangular waveform or a substantially rectangular waveform.

In order to attain the object, according to the shift register circuit of the present invention, the switching element is a thin film transistor (TFT).

According to the configuration, the switching element is a TFT in which a large amount of leakage between a drain and a source in the, subthreshold region. This makes it possible to noticeably prevent the second clock signal from being affected by an interconnect delay caused by the leakage.

In order to attain the object, according to the shift register circuit of the present invention: the first circuit connects, to a low voltage supply, a predetermined part of the each of the plurality of shift registers.

According to the configuration, circuit for causing each output terminal of a corresponding one of the plurality of shift registers SR to become a low level, can be driven at an appropriate timing.

In order to attain the object, according to the shift register circuit of the present invention: the predetermined part is a communication channel for the output signal.

According to the configuration, it is possible to cause the path of the output signal to become a low level by driving the first circuit with the second clock signal during an appropriate period in which the first clock signal is not transmitted to the output terminal.

In order to attain the object, the shift register circuit of the present invention is made of amorphous silicon.

According to the configuration, it is possible to cause, during an appropriate period, a floating part, which is peculiar to the shift register circuit made of amorphous silicon, to become a low level. Note that such a floating part can be generated in a case where, for example, the shift register circuit has to be made up of only n-channel TFTs.

In order to attain the object, the shift register circuit of the present invention is made of polycrystalline silicon.

According to the configuration, it is possible to cause an output terminal of a shift register to become a low level, during an appropriate period in the shift register circuit made of polycrystalline silicon.

In order to attain the object, the shift register circuit of the present invention is made of Continuous Grain (CG) silicon.

According to the configuration, it is possible to cause an output terminal of a shift register to become a low level, during an appropriate period in the shift register circuit made of CG silicon.

In order to attain the object, the shift register circuit of the present invention is made of microcrystalline silicon.

According to the configuration, it is possible to cause an output terminal of a shift register to become a low level, during an appropriate period in the shift register circuit made of microcrystalline silicon.

In order to attain the object, a display device of the present invention includes the shift register circuit for driving a display.

According to the configuration, it is possible to stabilize the operation of the shift register circuit. This makes it possible to carry out an excellent display.

In order to attain the object, the display device of the present invention further includes: at least one buffer circuit which is provided for respective of the at least one clock signal which constitute the second clock signal, each of the at least one buffer circuit being connected with a fall time extending circuit which extends fall time of a clock pulse of an output of the at least one buffer circuit, and an output of the fall time extending circuit being used as a clock signal which constitutes the first clock signal.

According to the configuration, the clock signal constituting the first clock signal is generated from the second clock signal with the use of the fall time extending circuit. This makes it possible to reduce the number of the buffer circuits, and thereby a configuration of the circuit can be simplified. Moreover, the second clock signal and the first clock signal, which is generated from the second clock signal, can share a voltage supply. This makes it possible to simplify the configuration of the voltage supply circuit.

In order to attain the object, the display device of the present invention further includes: at least one first buffer circuit which is provided for outputting each original clock signal from which at least one of the at least one clock signal, which constitutes the first clock signal, is generated; and at least one second buffer circuit which is provided for outputting respective of the at least another one clock signal, which constitutes the second clock signal, each of the at least one first buffer circuit being connected with a fall time extending circuit which extends fall time of a clock pulse of the original clock signal outputted from the at least one first buffer circuit, and an output supplied from the fall time extending circuit constituting the first clock signal.

According to the configuration, the clock signal constituting the first clock signal is generated with the use of the buffer circuit which is independent from the second clock signal. Accordingly, the clock signal constituting the first clock signal can be generated with the use of the buffer circuit which is configured in accordance with a necessary signal voltage.

In order to attain the object, according to the display device of the present invention, the fall time extending circuit is a CR delay circuit.

According to the configuration, it is possible to easily configure the fall time extending circuit.

In order to attain the object, according to the display device of the present invention, the shift register circuit is used as a scan signal line driving circuit.

According to the configuration, it is possible to stably cause the scan signal line to become a low level, and therefore an excellent display can be carried out.

In order to attain the object, according to the display device of the present invention, the shift register circuit and a display area are monolithically provided in a display panel.

According to the configuration, the shift register circuit and the display area are monolithically provided in the display panel. That is, the display device can be simply configured. In addition to this, the shift register circuit can be operated stably, and therefore an excellent display can be carried out.

In order to attain the object, a method of the present invention includes the steps of: supplying to the shift register circuit (i) a first clock signal which is made up of at least one clock signal and (ii) a second clock signal which is made up of at least one clock signal; and causing each of a plurality of shift registers which are connected to each other in series to receive (i) a predetermined one of the first clock signal, which is to be transmitted to an output terminal of the each of the plurality of shift registers via a corresponding switching element and then outputted as a corresponding output signal and (ii) a predetermined one of the second clock signal, which serves as a signal for driving a first circuit included in the each of the plurality of shift registers, in a case where the shift register circuit serves as a load on first and second supply lines, via which the first clock signal and the second clock signal are respectively supplied, under a non-load condition of the supply lines, fall time of a clock pulse of the first clock signal, which is supplied via the first supply line, being longer than that of the second clock signal, which is supplied via the second supply line.

According to the configuration, it is possible to realize a method for driving a shift register circuit which can prevent malfunction from occurring due to an interconnect delay of a clock signal, even though each shift register has a configuration in which (i) one clock signal is supplied as an output signal of the each shift register and (ii) the other clock signal is supplied as a driving signal of the each shift register.

Moreover, even in a case where a so-called feed-through phenomenon occurs via a picture element electrode and a gate line after a data signal is written into a picture element in a liquid crystal display panel, feed-through voltages ΔV become uniform in the panel plane. This greatly contributes to a display with high quality.

In order to attain the object, according to the method of the present invention, the first clock signal and the second clock signal have (i) identical High-level voltages and (ii) identical Low-level voltages.

According to the configuration, it is possible to reduce a size of a voltage supply circuit which supplies a voltage to the shift register circuit. Moreover, it is possible to enhance a driving capability of the first circuit.

In order to attain the object, according to the method of the present invention, the first clock signal has a waveform which is obtained by delaying, in accordance with a time constant, a waveform of any one of the clock signals which constitute the second clock signal.

According to the configuration, the first clock signal can be easily generated from a rectangular wave with the use of a device such as a CR delay circuit.

### Advantageous Effects of Invention

As described above, in the shift register circuit of the present invention, (i) a first clock signal which is made up of at least one clock signal and (ii) a second clock signal which is made up of at least one clock signal, are supplied to said shift register circuit, the shift register circuit includes: a plurality of shift registers which are connected to each other in series; each of the plurality of shift registers receives (i) a predetermined one of the first clock signal, which is to be transmitted to an output terminal of the each of the plurality of shift registers via a corresponding switching element and then outputted as a corresponding output signal and (ii) a predetermined one of the second clock signal, which serves as a signal for driving a first circuit included in the each of the plurality of shift registers; and in a case where said shift register circuit serves as a load on first and second supply lines, via which the first clock signal and the second clock signal are respectively supplied, under a non-load condition of the supply lines, fall time of a clock pulse of the first clock signal, which is supplied via the first supply line, is longer than that of the second clock signal, which is supplied via the second supply line.

This makes it possible to realize a shift register circuit which can prevent malfunction from occurring due to an interconnect delay of a clock signal, even though each shift register has a configuration in which (i) one clock signal is supplied as an output signal of the each shift register and (ii) the other clock signal is supplied as a driving signal of the each shift register.

### BRIEF DESCRIPTION OF DRAWINGS

FIG. 1 is an explanatory view illustrating a shift register circuit of an embodiment of the present invention, where (a) is a circuit diagram illustrating a configuration of each of shift registers, and (b) is a timing chart illustrating specific waveforms in an operation of the configuration shown in (a) of FIG. 1.

FIG. 2 is a circuit block diagram illustrating a configuration of a shift register circuit including the shift registers each configured as shown in FIG. 1.

FIG. 3 is a timing chart for explaining a first operation of each of the shift registers configured as shown in FIG. 1.

FIG. 4 is a timing chart for explaining a second operation of each of the shift registers configured as shown in FIG. 1.

FIG. 5 is a block diagram illustrating a configuration of a display device in an embodiment of the present invention.

FIG. 6 is a block diagram illustrating a first configuration of a control board included in the display device shown in FIG. 5.

FIG. 7 is a block diagram illustrating a second configuration of a control board included in the display device shown in FIG. 5.

FIG. 8 is a timing chart illustrating waveforms in an operation of a modification of each of shift registers in an embodiment of the present invention.

FIG. 9 is a circuit block diagram illustrating a configuration of a first shift register circuit of a conventional technique.

FIG. 10 is a circuit diagram illustrating a configuration of each of shift registers included in the shift register circuit shown in FIG. 9.

FIG. 11 is a timing chart illustrating an operation of each of the shift registers configured as shown in FIG. 10.

FIG. 12 is a circuit block diagram illustrating a configuration of a second shift register circuit of a conventional technique.

FIG. 13 is a circuit diagram illustrating a configuration of each of shift registers included in the shift register circuit shown in FIG. 12.

FIG. 14 is a timing chart illustrating an operation of each of the shift registers configured as shown in FIG. 13.

FIG. 15 is a graph illustrating relations between shift amounts of threshold voltages of TFTs and stressing time period.

### DESCRIPTION OF EMBODIMENTS

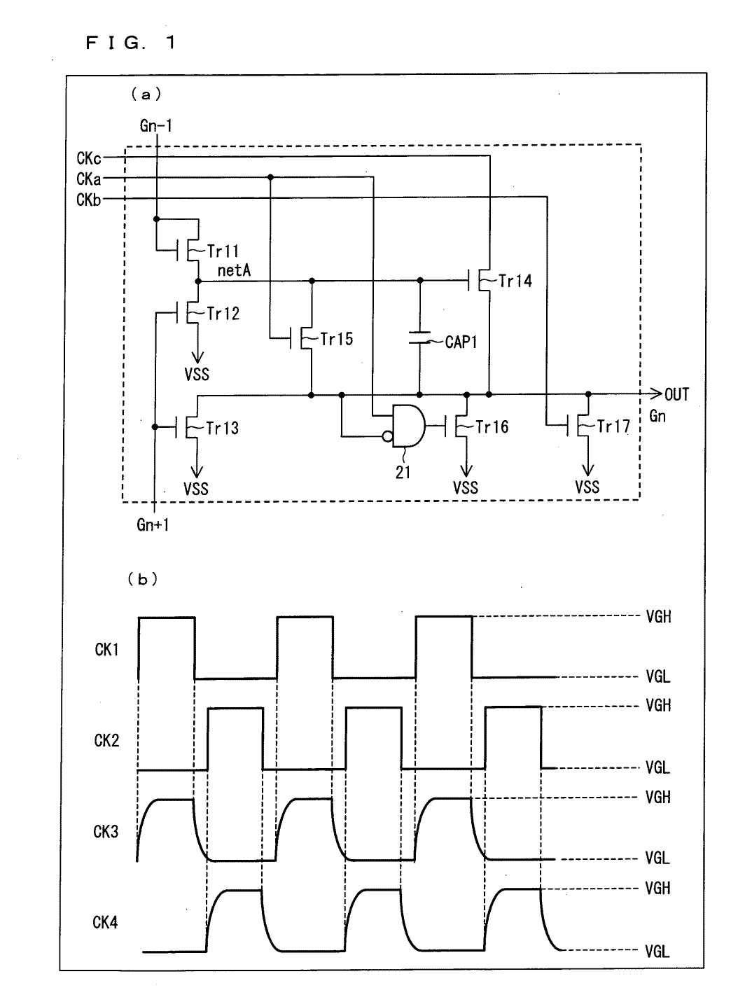

The following describes an embodiment of the present invention with reference to FIGS. 1 through 8.

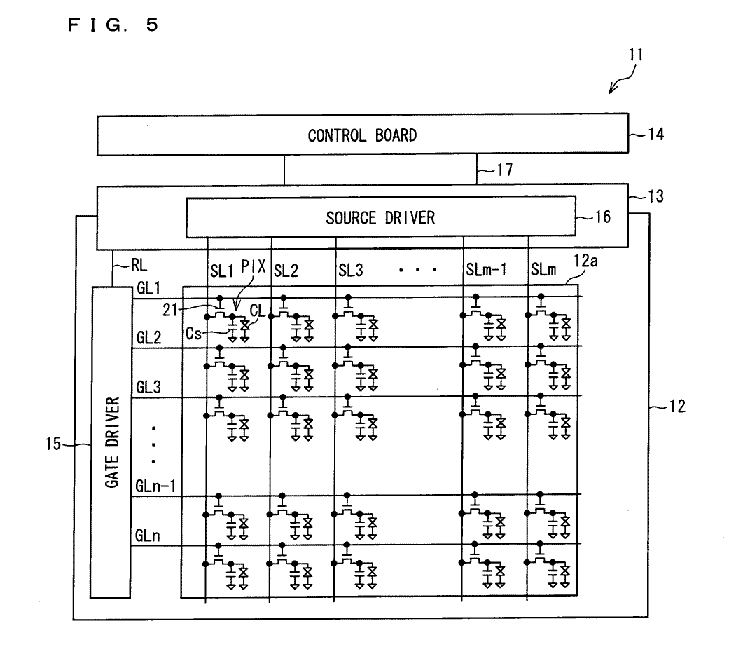

FIG. 5 illustrates a configuration of a liquid crystal display device 11 which is a display device of the present embodiment.

The liquid crystal display device 11 includes a display panel 12, a flexible printed wiring board 13, a control board 14, and a flexible connection wiring 17.

The display panel 12 is an active matrix display panel in which a display area 12a, a plurality of gate lines (scan signal lines) GL, a plurality of source lines (data signal lines) SL, and a gate driver (scan signal line driving circuit) 15 are formed on a glass substrate with the use of amorphous silicon. Alternatively, the display panel 12 can be can be made of a material such as polycrystalline silicon, CG (Continuous Grain) silicon, or microcrystalline silicon. In the display area 12a, a plurality of picture elements PIX are provided in a matrix manner. In each of the picture elements PIX, there are provided (i) a TFT 21, which is a element for selecting corresponding ones of the picture elements PIX, (ii) a liquid crystal capacitor CL, and (iii) a storage capacitor Cs. The TFT 21 has (i) a gate which is connected with a corresponding one of the gate lines GL, (ii) a source which is connected with a corresponding one of the source lines SL, and (iii) a drain which is connected with the liquid crystal capacitor CL and the storage capacitor Cs.

The plurality of gate lines GL are made up of gate lines GL1, GL2, GL3, . . . , and GLn, which are connected to respective output terminals of the gate driver (scan signal line driving circuit) 15. The plurality of source line SL are made up of source lines SL1, SL2, SL3, . . . , and SLn, which are connected to respective output terminals of a source driver 16, which will be described later. Moreover, there are provided storage capacitor lines (not illustrated) via which respective storage capacitor voltages are supplied to the storage capacitors Cs of the respective plurality of picture elements PIX.

The gate driver 15 is provided in an area, on the display panel 12, which area is adjacent to one side of the display area 12a in a direction in which the plurality of gate lines GL extend. The gate driver 15 sequentially supplies gate pulses (scan pulses) to the respective plurality of gate lines GL. The gate driver 15 and the display area 12a are monolithically provided in the display panel 12 with the use of a material such as amorphous silicon, polycrystalline silicon, CG silicon, or microcrystalline silicon. The gate driver 15 encompasses gate drivers each of which is referred to as “monolithic gate driver”, “gate driver-free”, “built-in gate driver in panel”, or “gate in panel”.

The source driver 16 is provided on the flexible printed wiring board 13. The source driver 16 supplies data signals to the respective plurality of source lines SL. The control board 14 is connected with the flexible printed wiring board 13 via the flexible connection wiring 17 so as to supply necessary signals and voltages to the gate driver 15 and the source driver 16. In the control board 14, (i) a clock signal which is to be supplied as a scanning signal and (ii) a clock signal which drives a circuit for causing the output terminal of a shift register to become a low level, are separately generated from a single clock signal by a level shifter circuit, as described later. The signals and voltages, which are supplied from the control board 14, are supplied to the gate driver 15, via the flexible connection wiring 17, the flexible printed wiring board 13, and a line (supply line) RL which is routed around on the display panel 12.

The gate driver 15, which is configured in a gate-monolithic manner, is suitable for use in a configuration in which (i) picture elements PIX, which constitute a single row, are all picture elements having identical colors and (ii) the gate driver 15 drives the plurality of gate lines GL separated for each of colors R, G, and B. According to such a configuration, it is not necessary to provide source drivers 16 for respective colors. This brings about an advantage of reducing of sizes of the source driver 16 and the flexible printed wiring board 13.

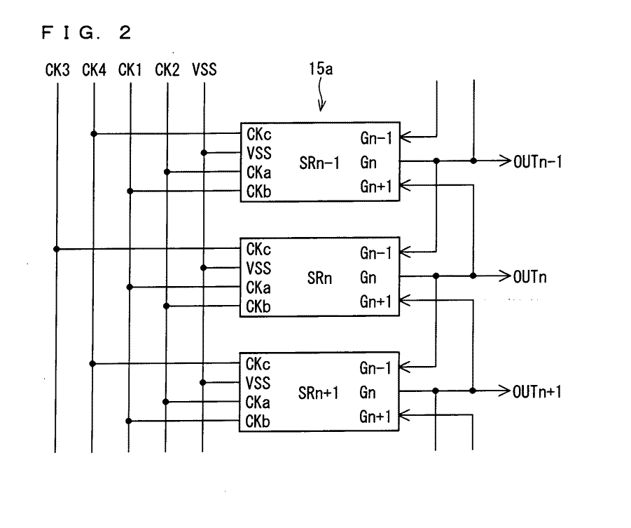

FIG. 2 illustrates a configuration example of the gate driver 15.

The gate driver 15 includes a shift register circuit 15a (see FIG. 2). According to the shift register circuit 15a, each of shift registers SR ( . . . , SRn-1, SRn, SRn+1, . . . ), which are connected to each other in series , has a set input terminal Gn-1, an output terminal Gn, a reset input terminal Gn+1, a Low-voltage supply input terminal VSS, and clock signal input terminals CKa, CKb, and CKc. An output signal OUT ( . . . , OUTn-1, OUTn, OUTn+1, . . . ) is supplied to the set input terminal Gn-1 from a followed shift register. A gate start pulse is supplied from the control board 14 via a set input terminal Gn-1 of a shift register SR1. The output signal OUT is supplied to a corresponding gate line GL, via the output terminal Gn. An output signal OUT of a shift register SR2, by which the shift register SR1 is followed, is supplied to the reset input terminal Gn+1 of the shift register SR1. A Low supply voltage VSS, which is a low-level supply voltage, is supplied to each of the shift registers SR, via a corresponding Low-voltage supply input terminal VSS.

In each of the shift registers SR, one of the clock signals CK1 and CK2 (second clock signal, driving signal), which are supplied from the control board 14, is supplied to one of the clock signal input terminals CKa and CKb, whereas the other of the clock signals CK1 and CK2 is supplied to the other of the clock signal input terminals CKa and CKb. Specifically, in the shift register SR1, (i) a clock signal CK1 is supplied via a clock signal input terminal CKa and (ii) a clock signal CK2 is supplied via a clock signal input terminal CKb. In the shift register SR2, (i) the clock signal CK2 is supplied via a clock signal input terminal CKa and (ii) the clock signal CK1 is supplied via a clock signal input terminal CKb. The shift registers SR are connected so that the shift register SR1 and shift register SR2 are alternated, in view of signal-supply relations of the clock signals CK1 and CK2 and the clock signal input terminals CKa and CKb.

In each of the shift registers SR, a clock signal CK3 or CK4 (first clock signal) is supplied via a corresponding clock signal input terminal CKc from the control board 14. Specifically, the shift registers SR are connected so that a clock signal CK3 is supplied to each clock signal input terminal CKc of shift registers each corresponding to the shift register SR1 and a clock signal CK4 is supplied to each clock signal input terminal CKc of shift registers each corresponding to the shift register SR2.

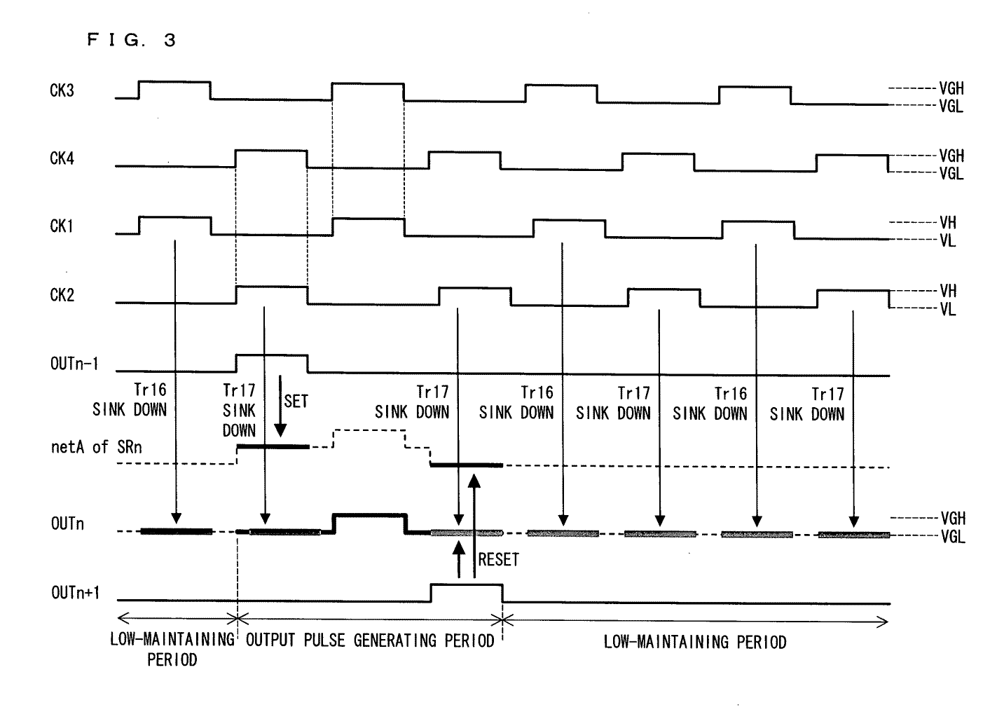

The clock signals CK1, CK2, CK3, and CK4 have respective waveforms as shown, for example, in FIG. 3. The clock signal CK1 and the clock signal CK2 have a phase relation in which active clock pulse periods of the clock signal CK1 and those of the clock signal CK2 do not overlap each other. Each of the clock signals CK1 and CK2 has a High-level voltage VH or a Low-level voltage VL. The clock signal CK3 changes at timing identical to that of the clock signal CK1. The clock signal CK4 changes at timing identical to that of the clock signal CK2. Each of the clock signals CK3 and CK4 has a High-level voltage VGH or a Low-level voltage VGL. Note that it is assumed that VGH>VH>0 and VGL=VL. Note also that VGL<VL can be alternatively satisfied.

The Low supply voltage VSS is equal to the Low-level voltage VGL of the clock signals CK3 and CK4. Further, the Low supply voltage VSS is assumed to be also equal to the Low-level voltage VL. Moreover, an AND gate 21 (later described) is assumed to have the High-level voltage VH or the Low-level voltage VL.

The clock signals CK1 and CK2 are obtained by converting, for example, a clock signal from 0V/3V sources into a clock signal from −7V/16V sources with the use of the level-shifter circuit in the control board 14. The clock signals CK3 and C4 are obtained by converting, for example, the clock signal from 0V/3V sources into a clock signal from −7V/22V sources with the use of the level-shifter circuit in the control board 14.

FIG. 1 is an explanatory view illustrating the shift register circuit 15a shown in FIG. 2 of an embodiment of the present invention. (a) of FIG. 1 illustrates a circuit configuration example of each of the shift registers SR included in the shift register circuit 15a shown in FIG. 2.

Each of the shift registers SR includes transistors Tr11, Tr12, Tr13, Tr14, Tr15, Tr16, and Tr17, a capacitor CAP1, and the AND gate 21. The transistors Tr11 through Tr17 are all n-channel TFTs.

The transistor Tr11 has (i) a gate and a drain which are connected with the set input terminal Gn-1 and (ii) a source which is connected with a gate of the transistor (switching element) Tr14. The transistor Tr14 has (i) a drain which is connected with the clock signal input terminal CKc and (ii) a source which is connected with the output terminal Gn. That is, the transistor Tr14 is a switching element which serves as a transfer gate to pass through or block off a clock signal to be supplied to the clock signal input terminal CKc. The capacitor CAP1 is provided between the gate and the source of the transistor Tr14. A node having an electric potential which is identical to that of the gate of the transistor Tr14 is referred to as a node netA (predetermined part).

The transistor Tr12 has (i) a gate which is connected with the reset input terminal Gn+1, (ii) a drain which is connected with the node netA, and (iii) a source connected with the Low-voltage supply input terminal VSS. The transistor Tr13 has (i) a gate which is connected with the reset input terminal Gn+1, (ii) a drain which is connected with the output terminal Gn, and (iii) a source which is connected with the Low-voltage supply input terminal VSS. The transistor Tr15 has (i) a gate which is connected with the clock signal input terminal CKa, (ii) a drain which is connected with the node netA, and (iii) a source which is connected with the output terminal Gn. The transistor Tr16 has (i) a gate which is connected with an output of the AND gate 21, (ii) a drain which is connected with the output terminal Gn, and (iii) a source which is connected with the Low-voltage supply input terminal VSS. The transistor Tr17 has (i) a gate which is connected with the clock signal input terminal CKb, (ii) a drain which is connected with the output terminal Gn, and (iii) a source which is connected to the Low-voltage supply input terminal VSS. The AND gate 21 has two input terminals one of which is connected with the clock signal input terminal CKa and the other, which is a low-active input terminal, is connected with the output terminal Gn.

The transistor Tr15, Tr16, and Tr17 are respective sink-down transistors. The transistor Tr15, Tr16, and Tr17 and the AND gate 21 constitute a first circuit which causes a communication channel, in each of the shift registers SR, such as the node netA and the output terminal Gn to be connected to the low-level voltage supply.

According to the present embodiment, (i) a clock signal (the first clock signal) which is outputted as a scanning signal and (ii) a clock signal (the second clock signal) which is supplied to a gate of a sink-down TFT are made different from each other. Note that, according to the present embodiment, the first clock signal is made up of the clock signals CK3 and CK4, and the second clock signal is made up of the clock signals CK1 and CK2. However, in general, each of the first and second clock signals can be at least one (1) clock signal, in accordance with a configuration of each of the shift registers SR.

The following describes operation of each of the shift registers SR having a circuit configuration shown in (a) of FIG. 1, with reference to FIG. 3.

The transistors Tr13 and Tr14 remain in a high-impedance state until a shift pulse is supplied to the set input terminal Gn-1. The output terminal Gn remains in a Low level (Law-maintaining period), accordingly. During the period, the transistor Tr15 turns on in response to a clock pulse of the clock signal CK1 or CK2 (clock signal CK1 in FIG. 3) which is supplied to the clock signal input terminal CKa. This causes the node netA to be conductively connected to the output terminal Gn. The AND gate 21 outputs a High level in response to a clock pulse of a clock signal (the clock signal CK1 in FIG. 3) which is supplied to the clock signal input terminal CKa as long as the output terminal Gn is in a Low level. This causes the transistor Tr16 to turn on. The transistor Tr17 turns on in response to a clock pulse of the clock signal CK1 or CK2 (clock signal CK2 in FIG. 3) which is supplied to the clock signal input terminal CKb. This causes the output terminal Gn to be electrically connected to the Low supply voltage VSS.

The output terminal Gn is caused to become a low level during a first period in which the transistor Tr16 is in the ON state and during a second period in which the transistor Tr17 is in the ON state, the first and second periods being alternated. Moreover, since the transistor Tr16 is in the ON state while the transistor Tr15 is in the

ON state, the node netA is caused to become a low level while the transistors Tr15 and Tr16 are in the ON state.

While a gate pulse, which is the shift pulse, of an output signal OUT (OUTn-1 in FIG. 3) is being supplied to the set input terminal Gn-1 from a followed shift register, (i) an output pulse is generated and outputted via the output terminal Gn and (ii) the transistor Tr11 is in an ON state so as to charge the capacitor CAP1. As the capacitor CAP1 is charged, an electric potential of the node netA increases so that the transistor Tr14 turns on. This causes a clock signal (clock signal CK3 in FIG. 3), which has been supplied to the clock signal input terminal CKc to be applied to the source of the transistor Tr14. At a moment when a clock pulse is supplied to the clock signal input terminal CKc, the electric potential of the node netA precipitously rises due to a bootstrap effect of the capacitor CAP1, and therefore the clock pulse thus supplied is outputted as a gate pulse (in this case, as a pulse of the output signal OUTn) via the output terminal Gn of the shift register SR.

When the supply of the gate pulse to the set input terminal Gn-1 ends, the transistor Tr11 turns off. Then, the transistors Tr12 and Tr13 are caused to turn on in response to a reset pulse supplied to the reset input terminal Gn+1 so that the Low supply voltage VSS is applied to the node netA and the output terminal Gn. This allows the electric charge, which has been caused by the floating of the node netA and the output terminal Gn of the shift register SR, to be discharged. Accordingly, the transistor Tr14 turns off. When the supply of the reset pulse ends, the output pulse generating period of the output terminal Gn ends, and another Low-maintaining period of the output terminal Gn newly starts.

Gate pulses are thus sequentially supplied to respective gate lines.

According to the operation shown in FIG. 3, the gates of the respective transistors Tr15, Tr16, and Tr17 are subjected to DC bias at the ON-duty ratio of approximately 50%, while the output terminal Gn is being connected to the Low level. Despite this, since the High-level voltage VH is set to be lower than the High-level voltage VGH, it is possible to drastically reduce a shift amount ΔVth of a threshold voltage of the sink-down TFT.

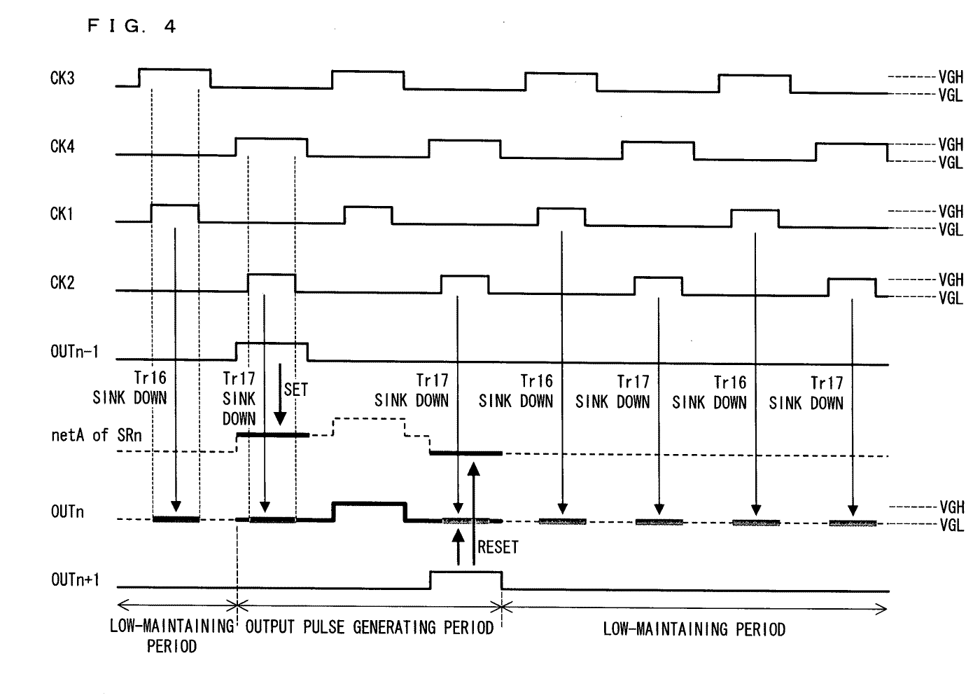

The following describes another method for driving the shift register circuit 15a having a circuit configuration shown in (a) of FIG. 1 and FIG. 2, with reference to FIG. 4.

FIG. 4 illustrates a driving method in which (i) each of the clock signals CK1, CK2, CK3, and CK4 has a High-level voltage VGH or a Low-level voltage VGL and (ii) each ON-duty ratio of the clock signals CK1 and CK2 is set to be shorter than that of the clock signals CK3 and CK4. The clock signals CK3 and CK4 are used as scanning signals, and therefore have ON-duty ratios which are identical to those shown in FIG. 3.

In this case, periods, during which the transistor Tr15, Tr16, and Tr17 causes the output terminal Gn of the shift register SR to become a low level, become shorter than the case shown in FIG. 3 (see FIG. 4). This makes it possible to reduce DC bias, as with the case shown in FIG. 3, even though the clock signals CK1 and CK2 have a high-level voltage like the High-level voltage VGH.

As such, it is possible to drastically reduce a shift amount ΔVth of a threshold voltage of the sink-down TFT.

Note that it is also possible to set the ON-duty ratios of the clock signals CK1 and CK2 to be shorter than those of the clock signals CK3 and CK4 as shown in FIG. 4, while the voltage levels of the clock signals CK1 through CK4 shown in FIG. 3 are being employed.

The present embodiment is exemplified by the case where the n-channel TFTs are used as shown in FIG. 3 and the High-level voltage of the second clock signal is set to be lower than the High-level voltage of the first clock signal. The present embodiment is, however, not limited to this. It is therefore possible to set the High-level voltage of the second clock signal to be higher than the High-level voltage of the first clock signal, while using n-channel TFTs.

For example, in a case where a TFT has a high threshold voltage, it is necessary to apply a high gate voltage in order for the TFT to sufficiently turn ON. It is, however, possible for the TFT to sufficiently turn ON, by appropriately setting the second clock signal, for example by reducing the ON-duty ratio, while causing the second clock signal to have a voltage level higher than that of the first clock signal. In this case, it is possible to appropriately set each duty ratio of active clock pulses of the second clock signal, in accordance with (i) the number of the sink-down TFTs and (ii) a period during which the sink-down TFTs cause the output terminal Gn of the shift register SR to become the low level. Accordingly, it is easier to reduce the DC bias, which is to be applied to the TFTs, as compared to a case where the first clock signal is used.

Moreover, the present embodiment is exemplified by the case where the n-channel TFT is used and each duty ratio of active clock pulses of the second clock signals is set to be shorter than that of the first clock signals (see FIG. 4). However, it is possible to set each duty ratio of active clock pulses of the second clock signals to be longer than that of the first clock signals, while using an re-channel TFT.

For example, in a case where a TFT has a threshold voltage of not high, the TFT sufficiently turns ON even when a gate voltage which is not so high is applied. Accordingly, it is possible for the TFT to sufficiently turn

ON by appropriately setting the second clock signal, for example, by causing the second clock signal to have (i) a reduced voltage level and (ii) each duty ratio of active clock pulses longer than that of the first clock signal. In this case, it is possible to appropriately set a voltage level of the second clock signal, in accordance with a threshold voltage. As such, it is easy to reduce the DC bias, which is to be applied to the TFT, as compared to a case where the first clock signal is used.

The following describes a configuration for generating clock signals required for the driving shown in FIGS. 3 and 4.

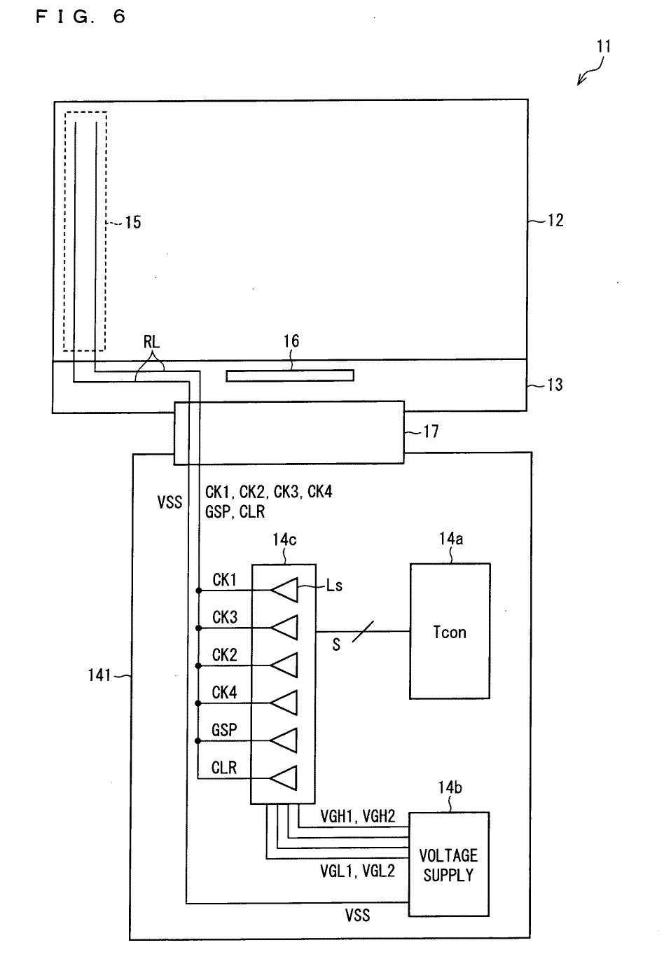

The clock signals CK1 through CK4 are generated by a control board 141 (see FIG. 6) which is a substitute for the control board 14 shown in FIG. 5. The control board 141 includes a timing signal generating circuit 14a, a voltage supply 14b, and a level-shifter circuit 14c.

The timing controller 14a generates, for example, clock signals CK1 through CK4, a gate start pulse GSP, and a clear signal CLR and then supplies the six signals S to the level-shifter circuit 14c before sending them to the gate driver 15. The clear signal CLR (not illustrated) is a signal which resets the shift register circuit 15a to an initial state. The voltage supply 14b generates supply voltages such as voltages VGH1, VGH2, VGL1, and VGL2 which are used by the level-shifter circuit 14c to generate the signals, and then supplies the voltages thus generated to the level-shifter circuit 14c. The voltage supply 14b further generates a Low supply voltage VSS, and then directly supplies the Low supply voltage VSS to the gate driver 15. For example, the voltages VGH1, VGH2, VGL1, and VGL2 respectively correspond to the voltages VGH, VH, VGL, and VL shown in FIG. 3.

The level-shifter circuit 14c includes buffer circuits Ls which output respective of the clock signals CK1 through CK4, the gate start pulse GSP, and the clear signal CLR. In a case of the driving shown in FIG. 3, the three buffer circuits Ls, which output respective of the clock signals CK1 and CK2 and the clear signal CLR, use voltages VGH2 and VGL2 as their supply voltages. Whereas, the three buffer circuits Ls, which output respective of the clock signals CK3 and CK4 and the gate start pulse GSP, use voltages VGH1 and VGL1 as their supply voltages. The clock signals CK1 through CK4, the gate start pulse GSP, and the clear signal CLR which are supplied from the level-shifter circuit 14c, and the Low supply voltage VSS are supplied to the gate driver 15 from the control board 141, via the flexible connection wiring 17, the flexible printed wiring board 13, and lines RL which are routed around on the display panel 12.

(b) of FIG. 1 illustrates an example of another waveforms of the clock signals CK1 through CK4 to be used in the configuration shown in (a) of FIG. 1.

According to the example, fall time of the clock signals CK3 and CK4 are set to be longer than those of the clock signals CK1 and CK2. As is generally defined, a fall time of a pulse is a time period required for an active-level pulse to fall from 90% to 10% in amplitude. In a case of a negative pulse whose active level is a Low level, the fall time is assumed to be a time period required for the negative pulse to change from the Low-level side toward the High-level side, i.e., a time period required for the negative pulse to fall from 90% to 10% in amplitude.

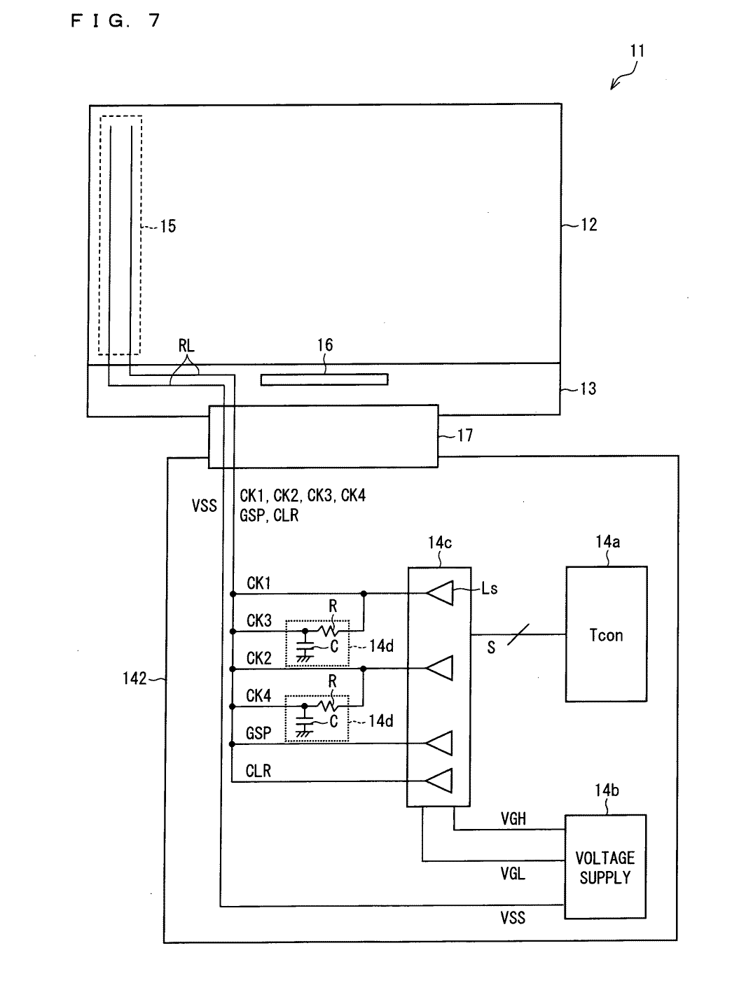

The clock signals CK1 through CK4 are generated by a control board 142 (see FIG. 7), which corresponds to the control board 14 shown in FIG. 5. The control board 142 includes a timing signal generating circuit 14a, a voltage supply 14b, a level-shifter circuit 14c, and fall time extending circuits 14d . . . .

The timing controller 14a generates, for example, clock signals CK1 and CK2, a gate start pulse GSP, and a clear signal CLR and then supplies the four signals S to the level-shifter circuit 14c before sending them to the gate driver 15. The clear signal CLR (not illustrated) is a signal which resets the shift register circuit 15a to an initial state. The voltage supply 14b generates supply voltages such as voltages VGH, VGL which are used by the level-shifter circuit 14c to generate the signals, and then supplies the voltages thus generated to the level-shifter circuit 14c. The voltage supply 14b further generates a Low supply voltage VSS, and then directly supplies the Low supply voltage VSS to the gate driver 15. The voltage VGH is a High-level voltage of the clock signals CK1 through CK4 shown in (b) of FIG. 1, and the voltage VGL is a Low-level voltage of the clock signals CK1 through CK4 shown in (b) of FIG. 1.

The level-shifter circuit 14c includes buffer circuits Ls which output respective of the clock signals CK1 and CK2, the gate start pulse GSP, and the clear signal CLR. Here, for all of the signals, the voltages VGH and VGL are used as supply voltages. Moreover, output terminals of the buffer circuits Ls for the respective clock signals CK1 and CK2 are connected with the fall time extending circuit 14d. The fall time extending circuit 14d is a CR delay circuit which has (i) an input terminal which is connected with one end of a resistor R and (ii) an output terminal which is connected with the other end of the resistor R and one end of a capacitor C. The other end of the capacitor C is connected with GND.

A clock signal CK1, which has been subjected to a corresponding level shift and supplied from a corresponding buffer circuit Ls, is (i) supplied, as it is, toward the display panel 12 and (ii) supplied to the fall time extending circuit 14d so as to be delayed in accordance with a time constant as shown in (b) of FIG. 1 and then outputted as a clock signal CK3.

A clock signal CK2, which has been subjected to a corresponding level shift and supplied from a corresponding buffer circuit Ls , is (i) supplied, as it is, toward the display panel 12 and (ii) supplied to the fall time extending circuit 14d so as to be delayed in accordance with a time constant as shown in (b) of FIG. 1 and then outputted as a clock signal CK4.

The waveforms of the respective clock signals CK1 through CK4 shown in (b) of FIG. 1 are obtained under a no-load condition in which the shift register circuit 15a, serving as a load, is not connected to the line RL. The no-load condition is a condition in which an input impedance, seen looking into the shift register circuit 15a from input terminals. The input terminals correspond to connection points (in this case, single-ended connection points) of the line RL and the shift register circuit 15a. For example, in a location where the line RL is connected with the gate of the transistor, a non-load condition can be substituted with a condition in which the line RL and the transistor are connected with each other. Whereas, in a location where the line RL is connected with a drain or a source of a transistor such as the transistor Tr4, whose OFF-leakage is large, a non-load condition can be replaced with a condition in which the line RL is disconnected from the transistor.

In this manner, the clock signals CK1 through CK4, the gate start pulse GSP, and the clear signal CLR, which are supplied from the level-shifter circuit 14c, and the Low supply voltage VSS are supplied to the gate driver 15 from the control board 142 via the flexible connection wiring 17, the flexible printed wiring board 13, and the lines RL which are routed around on the display panel 12.

According to the configuration in which the waveforms shown in (b) of FIG. 1 are used, each of the plurality of shift registers receives (i) a predetermined one of the clock signals CK3 and CK4 (first clock signals delayed as described above), which is to be transmitted via the transistor Tr14 and then outputted as a corresponding output signal OUT, and (ii) a predetermined one of the clock signals CK1 and CK2 (second clock signals) which serves as a signal for driving the first circuit made up of the transistors Tr15, Tr16, and Tr17, and the AND gate 21 included in the each of the plurality of shift registers.

This prevents the waveforms of the clock signals CK1 and CK2 from being affected, even in a case where a line, which is connected to the output terminal of each of the plurality of shift registers SR, serves as a load on the clock signals CK3 and CK4 (i) when the transistor Tr14 turns ON and (ii) when a leakage occurs in a subthreshold region while the transistor Tr14 is turning OFF, as with the case of the configuration shown in FIGS. 3 and 4. Therefore, it is possible to set a timing at which the first circuit is driven by the clock signals CK1 and CK2 independently from timing of the clock signals CK3 and CK4.

Under the non-load condition, the fall time of the clock pulses of the clock signals CK3 and CK4, which are supplied via the supply lines which are included in the line RL, is longer than that of the clock signals CK1 and CK2, which are supplied via the supply lines which are included in the line RL. This makes it possible to prevent a fall time from being increased due to a further interconnect delay, even in a case where a gate line becomes a load on the clock signals CK3 and CK4. The gate line is a line which is connected to the output terminal Gn of each of the plurality of shift registers 15a via the transistor Tr14 which turns ON or OFF.

A relation of phases of the clock signals CK1 through CK4 are easily set in advance so that the shift register circuit 15a hardly has malfunction, by taking a measure such as (i) avoiding active periods of the clock signals CK1 and CK4 from overlapping each other under the non-load condition and (ii) avoiding active periods of the clock signals CK2 and CK3 from overlapping each other under the non-load condition. According to the configuration shown in (b) of FIG. 1 for example, (i) the clock signal CK1 is set to have a phase whose active period is present between (a) a timing at which a falling edge of a clock pulse of the clock signal CK4 ends and (b) a timing at which a rising edge of a next clock pulse of the clock signal CK4 starts and (ii) the clock signal CK2 is set to have a phase whose active period is present between (c) a timing at which a falling edge of a clock pulse of the clock signal CK3 ends and (d) a timing at which a rising edge of a next clock pulse of the clock signal CK3 starts.

This makes it possible to realize a shift register circuit which can prevent malfunction from occurring due to an interconnect delay of a clock signal, even though each shift register has a configuration in which (i) one clock signal is supplied as an output signal of the each shift register and (ii) the other clock signal is supplied as a signal for driving the each shift register.

The clock signals CK3 and CK4 are supplied to the gate line from the shift register circuit 15a. In a case where each fall time of the clock pulses of the clock signals CK3 and CK4 is set to be sufficiently long before the clock pulses are supplied to the shift register circuit 15a, it is easy to prevent the fall time from being further increased due to an interconnect delay when the clock signals CK3 and CK4 are supplied to the gate line. This allows each fall time of the gate pulses to be substantially uniform in the panel plane. Therefore, feed-through voltages ΔV become uniform in the panel plane, even in a case where a so-called feed-through phenomenon occurs via a parasitic capacitor defined by a picture element electrode and the gate line after a data signal is written into a picture element PIX in the display panel 12. This greatly contributes to a display with high quality.

According to the configuration in which the waveforms shown in (b) of FIG. 1 are used, the clock signals CK3 and CK4 and the clock signals CK1 and CK2 have (i) identical High-level voltages and (ii) identical Low-level voltages. It follows that the clock signals CK3 and CK4 and the clock signals CK1 and CK2 can share a single voltage supply. This makes it possible to reduce a size of a voltage supply circuit which supplies voltages to the shift register circuit 15a. Moreover, an amplitude of each clock pulses of the clock signals CK1 and CK2 becomes equal to a large amplitude of each clock pulse of the clock signals CK3 and CK4, which are used as output signals of the shift register circuit 15a, and therefore the pulse comes to have higher electric power. This makes it possible to enhance a driving capability of the first circuit.

According to the configuration in which the waveforms shown in (b) of FIG. 1 are used, the clock signal CK3 has a waveform which is obtained by delaying, in accordance with a time constant, a waveform of any one of the clock signals which constitute the clock signal CK1, and the clock signal CK4 has a waveform which is obtained by delaying, in accordance with a time constant, a waveform of any one of the clock signals which constitute the clock signal CK2. Accordingly, it is possible to easily generate, with the use of a circuit such as a CR delay circuit, the clock signals CK3 and CK4 from the clock signals CK1 and CK2 each of which has a rectangular waveform or a substantially rectangular waveform.

According to the configuration in which the waveforms shown in (b) of FIG. 1 are used, the transistor Tr4, serving as the switching element, is a TFT in which a large amount of leakage occurs between the drain and the source in the subthreshold region. This makes it possible to noticeably prevent the clock signals CK1 and CK2 from being affected by an interconnect delay caused by the leakage.

According to the configuration in which the waveforms shown in (b) of FIG. 1 are used, a circuit for causing each output terminal of a corresponding one of the plurality of shift registers SR to become a low level, can be driven at an appropriate timing.

According to the examples shown in (b) of FIG. 1 and FIG. 7, the clock signals CK3 and CK4 have respective waveforms which are obtained by delaying, in accordance with a time constant, the whole waveforms of the clock signals CK1 and CK2. This causes each clock pulse of the clock signals CK3 and CK4 to have the fall time and rise time, as well, which are longer than those of each clock pulse of the clock signals CK1 and CK2. However, the present embodiment is not limited to the waveforms. For example, the clock signals CK3 and CK4 can be arranged (i) so as to have clock pulses each having a waveform which is obtained by switching and combining different waveforms that have the respective following periods: (a) a pulse period including an inclined fall time and (b) a voltage VGL period, which are switched alternately and (ii) so as to have respective waveforms whose fall time is longer than that of each of the clock signals CK1 and CK2.

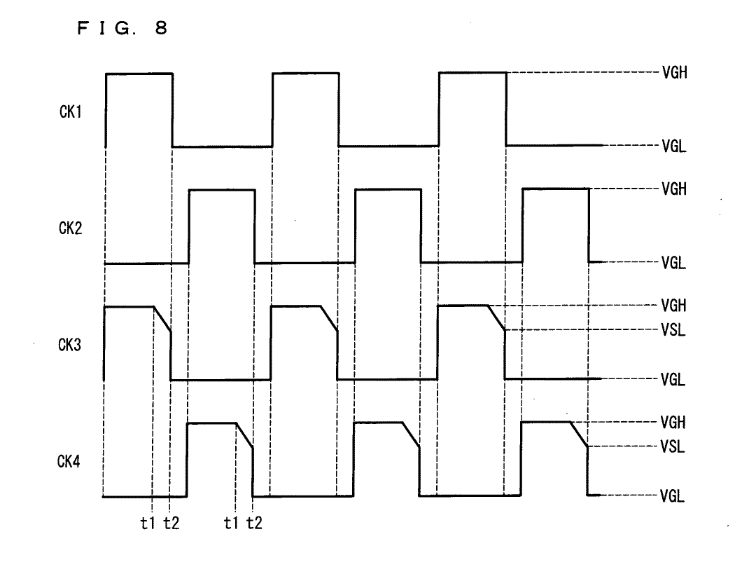

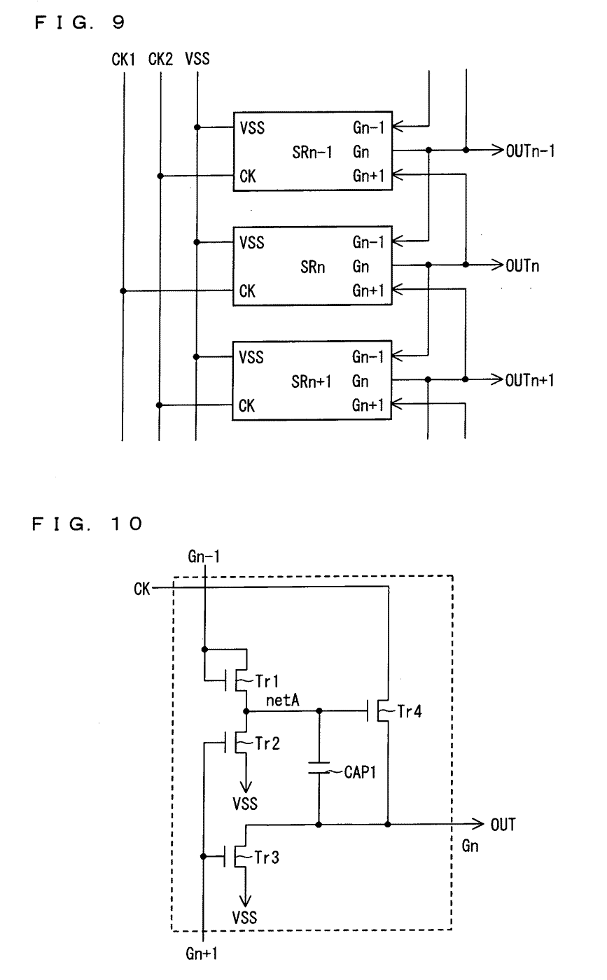

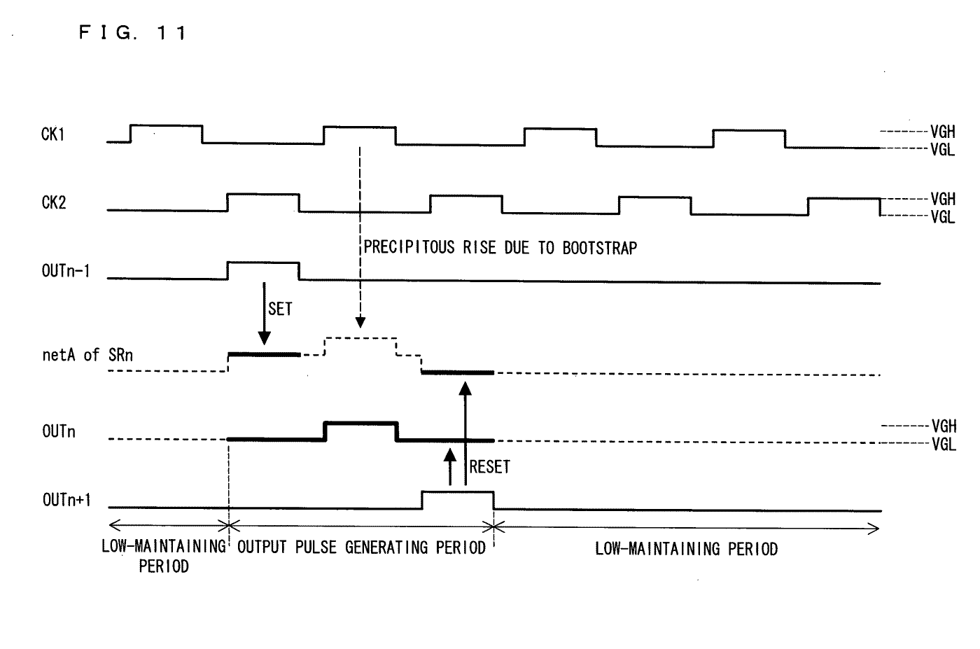

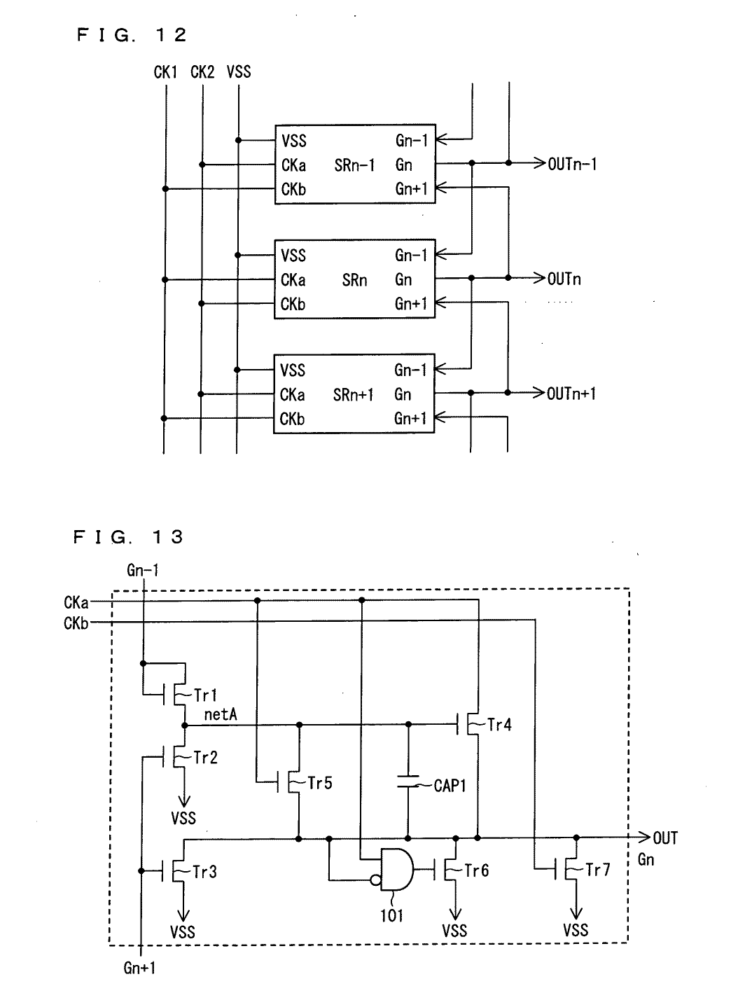

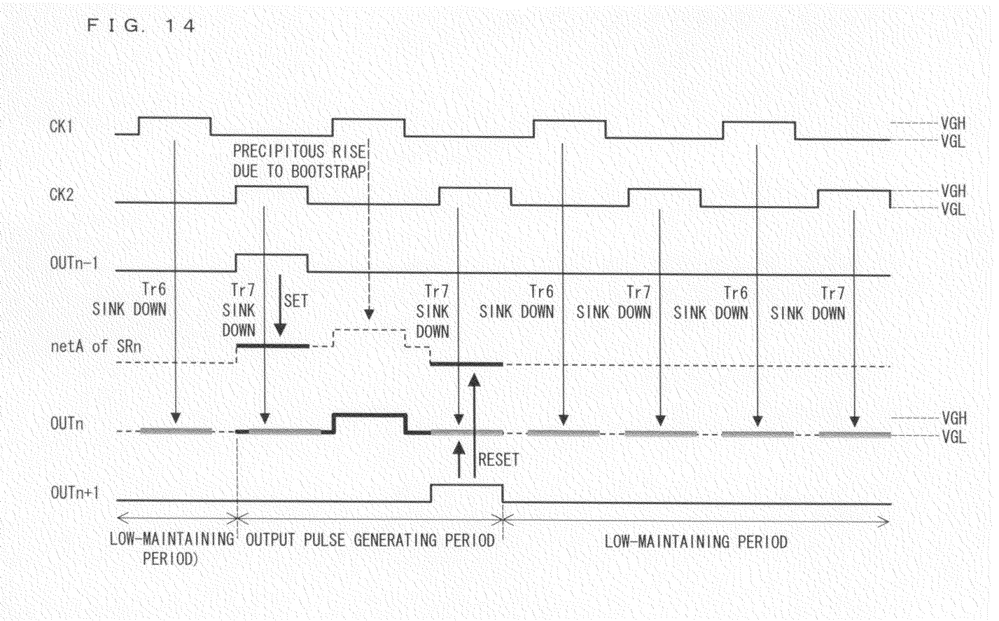

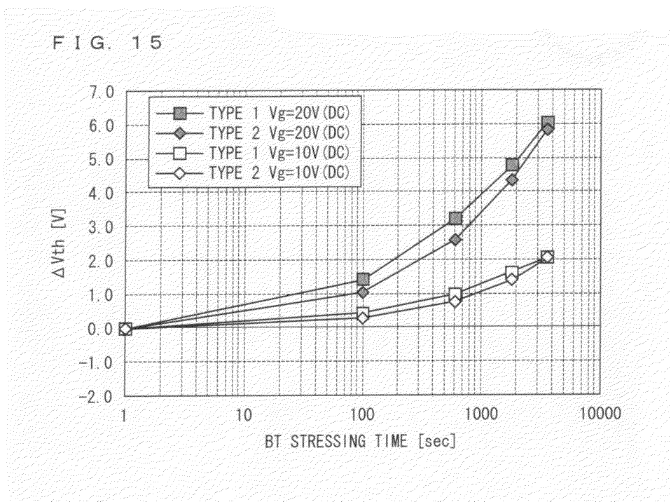

FIG. 8 illustrates an example of the waveforms described above. Although FIG. 8 shows that the clock signals CK1 and CK2 have waveforms which are identical to those shown in (b) of FIG. 1, whereas each of the clock signals CK3 and CK4 has a waveform in which its pulse (i) precipitously rises as with those of the clock signals CK1 and CK2 and (ii) falls from a time point t1 to a time point t2 so as to have (a) a decline from a voltage VGH to a voltage VSL which falls in a range of the voltage VGH to a voltage VGL and (b) a precipitous change to the voltage VGL substantially at the end of such a decline. Therefore, each fall time of the clock signals CK3 and CK4 is longer than those of the clock signals CK1 and CK2. The voltage VSL can be a level which causes the TFT 21 of the picture element PIX to change to a turn-off state from a turn-ON state. Alternatively, the voltage VSL does not necessarily have such a level.

In a case of providing the clock signals CK3 and CK4 each precipitously rising, in a very short period, with the use of such a configuration in which a plurality of waveforms are combined, it is possible to enhance a bootstrap effect of the capacitor CAP1 as shown in (a) of FIG. 1. This makes it possible to output, via the output terminal Gn, the clock signals CK3 and CK4 as an output signal OUT with small distortion.

According to the example shown in (b) of FIG. 1 and FIG. 7, each of at least one buffer circuit Ls is provided which outputs a clock signal constituting the second clock signal, and a fall time extending circuit 14d, which extends the fall time of a clock pulse supplied from the each of at least one buffer circuit Ls, is connected with an output terminal of the each of at least one buffer circuit Ls. The fall time extending circuit 14d outputs a clock signal which constitutes the first clock signal. Note that the clock signals constituting the first clock signals do not necessarily need to be respectively combined with all the second clock signals via the respective fall time extending circuits 14d, provided that the number of the buffer circuits Ls is identical to that of the first clock signals to be generated from the second clock signals. Further, it is not necessary that all the clock signals which constitute the first clock signal are generated from respective clock signals which constitute the second clock signal with the use of respective fall time extending circuits 14d.

According to the configuration, each clock signal which constitutes the first clock signal is generated from a corresponding clock signal which constitutes the second clock signal with the use of a corresponding fall time extending circuit 14d. This makes it possible to reduce the number of the buffer circuits Ls, and therefore a circuit configuration can be simplified. Moreover, this allows (i) a clock signal which constitute the first clock signal which is generated from a corresponding clock signal which constitutes the second clock signal and (ii) the corresponding clock signal which constitutes the second clock signal, to share a single voltage supply, and therefore the configuration of a required voltage supply circuit can be simplified.

According to the examples shown in (b) of FIG. 1 and FIG. 7, at least one buffer circuit (first buffer circuit) Ls, which outputs an original clock signal from which at least one clock signal which constitutes the first clock signal is generated, is provided for each of the at least one clock signal that constitutes the first clock signal. Moreover, a buffer circuit (second buffer circuit) Ls, which outputs a clock signal which constitutes the second clock signal, is provided for each of the at least one clock signal which constitutes the second clock signal. Each of the first buffer circuits has an output terminal which is connected with a corresponding fall time extending circuit 14d which (i) extends fall time of a clock pulse of the original clock signal and (ii) outputs a clock signal which constitutes the first clock signal.

Here, it is sufficient that the number of the at least one buffer circuit Ls, which output the original clock signal which constitutes the first clock signal, is equal to that of the clock signals which constitute the first clock signal which is to be generated independently from the second clock signal.

According to the configuration, a predetermined clock signal which constitutes the first clock signal is generated with the use of a corresponding buffer circuit Ls which is independent from the second clock signal. This makes it possible to generate the predetermined clock signal which constitutes the first clock signal with the use of a buffer circuit Ls having a configuration suitable for a necessary signal power.

Moreover, the waveforms shown in (b) of FIG. 1 can have (i) the relation of the High-level voltage and the Low-level voltage of the clock signals CK1 through CK4 as shown in FIG. 3, and (ii) the relation of pulse widths of the clock signals CK1 through CK4 as shown in FIG. 4. In cases where the relations of the High-level voltage and Low-level voltage of the clock signals CK1 through CK4 are as shown in FIG. 3 and (b) of FIG. 1, it is possible to cause the level-shifter circuit 14c shown in FIG. 7 to be provided with buffer circuits for outputting respective clock signals CK1 and CK2 and original clock signals of the clock signals CK3 and CK4.

The above discussed the present embodiment. The present invention can be applied to another display device, such as an EL display device, which includes a shift register circuit.

The present invention is not limited to the embodiments, but can be altered by a skilled person in the art within the scope of the claims. An embodiment derived from a proper combination of technical means disclosed in respective different embodiments is also encompassed in the technical scope of the present invention.

### INDUSTRIAL APPLICABILITY

The present invention can be particularly suitably used for a display device such as a liquid crystal display device or an EL display device.

### REFERENCE SIGNS LIST

11: Liquid crystal display device (display device)

14d: Fall time extending circuit (CR circuit)

15a: Shift register circuit

VGH: High-level voltage

VGL: Low-level voltage

SR: Shift register

CK1 and CK2: Clock signal (second clock signal)

CK3 and CK4: Clock signal (first clock signal)

netA: Node (predetermined part, path for output signal)

Gn: Output terminal (predetermined part, path for output signal)

OUT: Output signal

Tr4, Tr15, Tr16, and Tr17: Transistor (switching element, TFT)

1. A shift register circuit in which (i) a first clock signal which is made up of at least one clock signal and (ii) a second clock signal which is made up of at least one clock signal, are supplied to said shift register circuit,
said shift register circuit, comprising:
a plurality of shift registers which are connected to each other in series,
each of the plurality of shift registers receiving (i) a predetermined one of the first clock signal, which is to be transmitted to an output terminal of the each of the plurality of shift registers via a corresponding switching element and then outputted as a corresponding output signal and (ii) a predetermined one of the second clock signal, which serves as a signal for driving a first circuit included in the each of the plurality of shift registers,
in a case where said shift register circuit serves as a load on first and second supply lines, via which the first clock signal and the second clock signal are respectively supplied,
under a non-load condition of the supply lines, fall time of a clock pulse of the first clock signal, which is supplied via the first supply line, being longer than that of the second clock signal, which is supplied via the second supply line.

2. The shift register circuit as set forth in claim 1, wherein:
the first clock signal and the second clock signal have (i) identical High-level voltages and (ii) identical Low-level voltages.

3. The shift register circuit as set forth in claim 1, wherein:
the first clock signal has a waveform which is obtained by delaying, in accordance with a time constant, a waveform of any one of the clock signals which constitute the second clock signal.

4. The shift register circuit as set forth in claim 1, wherein the switching element is a thin film transistor (TFT).

5. The shift register circuit as set forth in claim 1, wherein:
the first circuit connects, to a low voltage supply, a predetermined part of the each of the plurality of shift registers.

6. The shift register circuit as set forth in claim 5, wherein:
the predetermined part is a communication channel for the output signal.

7. A shift register circuit recited in claim 1 which is made of amorphous silicon.

8. A shift register circuit recited in claim 1 which is made of polycrystalline silicon.

9. A shift register circuit recited in claim 1 which is made of Continuous Grain (CG) silicon.

10. A shift register circuit recited in claim 1 which is made of microcrystalline silicon.

11. A display device comprising a shift register circuit recited in claim 1, the shift register circuit being used to drive a display.

12. The display device as set forth in claim 11, further comprising:
at least one buffer circuit which is provided for respective of the at least one clock signal which constitute the second clock signal,
each of the at least one buffer circuit being connected with a fall time extending circuit which extends fall time of a clock pulse of an output of the at least one buffer circuit, and
an output of the fall time extending circuit being used as a clock signal which constitutes the first clock signal.

13. The display device as set forth in claim 11, further comprising:
at least one first buffer circuit which is provided for outputting each of at least one original clock signal from which at least one of the at least one clock signal, which constitutes the first clock signal, is generated; and
at least one second buffer circuit which is provided for outputting respective of the at least another one clock signal, which constitutes the second clock signal,
each of the at least one first buffer circuit being connected with a fall time extending circuit which extends fall time of a clock pulse of the original clock signal outputted from the at least one first buffer circuit, and
an output supplied from the fall time extending circuit constituting the first clock signal.

14. The display device as set forth in claim 12, wherein the fall time extending circuit is a CR delay circuit.

15. The display device as set forth in claim 11, wherein the shift register circuit is used as a scan signal line driving circuit.

16. The display device as set forth in claim 11, wherein the shift register circuit and a display area are monolithically provided in a display panel.

17. A method for driving a shift register circuit, comprising the steps of:
supplying to the shift register circuit (i) a first clock signal which is made up of at least one clock signal and (ii) a second clock signal which is made up of at least one clock signal; and
causing each of a plurality of shift registers which are connected to each other in series to receive (i) a predetermined one of the first clock signal, which is to be transmitted to an output terminal of the each of the plurality of shift registers via a corresponding switching element and then outputted as a corresponding output signal and (ii) a predetermined one of the second clock signal, which serves as a signal for driving a first circuit included in the each of the plurality of shift registers, p1 in a case where the shift register circuit serves as a load on first and second supply lines, via which the first clock signal and the second clock signal are respectively supplied,
under a non-load condition of the supply lines, fall time of a clock pulse of the first clock signal, which is supplied via the first supply line, being longer than that of the second clock signal, which is supplied via the second supply line.

18. The method as set forth in claim 17, wherein:
the first clock signal and the second clock signal have (i) identical High-level voltages and (ii) identical Low-level voltages.

19. The method as set forth in claim 17, wherein:
the first clock signal has a waveform which is obtained by delaying, in accordance with a time constant, a waveform of any one of the clock signals which constitute the second clock signal.
